(19) United States
(12) Patent Application Publication
(10) Pub. No.: US 2018/0312398 A1
(43) Pub. Date: Nov. 1, 2018

(54) MANUFACTURING METHOD OF SENSOR USING 3D PRINTING AND 3D PRINTER THEREOF

(71) Applicants: Electronics and Telecommunications Research Institute, Daejeon (KR); TECHNISCHE UNIVERSITAT DARMSTADT, Darmstadt (DE)

(72) Inventors: Woo Sug JUNG, Daejeon (KR); Hwa Suk KIM, Daejeon (KR); Jun Ki JEON, Daejeon (KR); Seong Kyoun JO, Sejong-si (KR); Sun Joong KIM, Sejong-si (KR); Hyun Woo LEE, Seoul (KR); Martin Schmitz, Darmstadt (DE); Florian Muller, Darmstadt (DE); Andreas Leister, Darmstadt (DE); Jan Riemann, Darmstadt (DE); Niloofar Dezfuli, Darmstadt (DE); Max Muhlhauser, Darmstadt (DE); Mohammed Khalilbeigi, Darmstadt (DE)

(73) Assignees: Electronics and Telecommunications Research Institute, Daejeon (KR); TECHNISCHE UNIVERSITAT DARMSTADT, Darmstadt (DE)

(21) Appl. No.: 15/588,076

(22) Filed: May 5, 2017

(30) Foreign Application Priority Data
Apr. 28, 2017 (KR) 10-2017-0054940

(51) Int. Cl. B81C 1/00; B81B 3/00; B33Y 80/00; B33Y 10/00; G01C 19/5769

(52) U.S. Cl. CPC B81C 1/00142; B81B 3/0062; G01P 15/0802; B33Y 10/00; G01C 19/5769; B33Y 80/00

(57) ABSTRACT

Disclosed is a manufacturing method of a sensor by using 3D printing and 3D printer therefor. According to an embodiment of the present disclosure, a manufacturing method of a sensor by using 3D printing includes: forming a first shape having an inner space by using a non-conductive material, and simultaneously or sequentially, forming an electrode at a preset location in the inner space by using a conductive material; injecting conductive liquid into the inner space; and forming a second shape on the first shape by using the non-conductive material to seal the inner space of the first shape.

### CROSS REFERENCE TO RELATED APPLICATION

The present application claims priority to Korean Patent Application No. 10-2017-0054940, filed Apr. 28, 2017, the entire contents of which is incorporated herein for all purposes by this reference.

### BACKGROUND OF THE INVENTION

### Field of the Invention

The present disclosure relates generally to a manufacturing method of a sensor by using 3D printing, and 3D printer thereof. More particularly, the present disclosure relates to a manufacturing method of tilt and motion sensors in which conductive liquid is injected by using 3D printing.

### DESCRIPTION OF THE RELATED ART

Wearable devices or the Internet of Things (IoT) devices have various electrical or mechanical sensors therein.

A tilt sensor for detecting a horizontal state of a device is called a horizontal sensor. A motion sensor detects motion of a user, with a tilt sensor. That is, tilt and motion sensors are used to track a position of a user or of a device by detecting a horizontal state and motion of the device. The tilt and motion sensors are necessary devices and technologies for tracking a position of a user in augmented/virtual reality technologies.

In the meantime, a 3D printer is a device for producing a three-dimensional object by using an additive manufacturing (AM) technique instead of conventional cutting processing technique. The 3D printer uses a 3D model that is digital design data, and various materials on a 3D printer component that is called a bed so as to produce an object.

When producing a sensor by using this 3D printing technique, a 3D printer produces an outer shape and then a circuit device having a sensor is provided therein, whereby tilt and motion sensors are produced. Accordingly, when producing a sensor as described above, there is a limit in reduction in size of the sensor and complexity is increased due to electric wires and additional logic for coupling the built-in sensor circuit device and external hardware. Thus, reliability of the sensor is degraded and costs are increased.

The foregoing is intended merely to aid in the understanding of the background of the present disclosure, and is not intended to mean that the present disclosure falls within the purview of the related art that is already known to those skilled in the art.

### SUMMARY OF THE INVENTION

Accordingly, the present disclosure has been made keeping in mind the above problems occurring in the related art, and the present disclosure is intended to propose a manufacturing method of tilt and motion sensors composed of conductive and non-conductive materials, and liquid by using 3D printing.

It is to be understood that technical problems to be solved by the present disclosure are not limited to the aforementioned technical problems and other technical problems which are not mentioned will be apparent from the following description to a person with an ordinary skill in the art to which the present disclosure pertains.

In order to achieve the above object, according to one aspect of the present disclosure, there is provided a manufacturing method of a sensor by using 3D printing, the manufacturing method including: forming a first shape having an inner space by using a non-conductive material, and simultaneously or sequentially, forming an electrode at a preset location in the inner space by using a conductive material; injecting conductive liquid into the inner space; and forming a second shape on the first shape by using the non-conductive material to seal the inner space of the first shape.

Here, the inner space of the first shape may have one of a polygonal shape and a half-pipe shape.

In the meantime, when the inner space of the first shape has the half-pipe shape, the preset location may be a location in a form of two straight lines along a bottom surface in the inner space.

In this case, the electrode may be formed to be exposed between the first shape and the second shape.

In the meantime, when the inner space of the first shape has the polygonal shape, the preset location may be a corner of a polygon.

In the meantime, the injecting of the conductive liquid into the inner space may be controlled based on a length of the electrode formed in the inner space.

In the meantime, the manufacturing method of the sensor by using 3D printing may use one 3D printing technique of fused deposition modeling (FDM), stereolithography (SLA), digital light processing (DLP), selective laser sintering (SLS), and selective laser melting (SLM).

According to another aspect of the present disclosure, there is provided a 3D printer for manufacturing a sensor, the 3D printer including: a non-conductive material forming unit forming a first shape having an inner space by using a non-conductive material; a conductive material forming unit forming an electrode at a preset location in the inner space by using a conductive material; a liquid injecting unit injecting conductive liquid into the inner space of the first shape; and a controller controlling the non-conductive material forming unit to form a second shape on the first shape by using the non-conductive material so as to seal the inner space of the first shape.

Here, the inner space of the first shape may have one of a polygonal shape and a half-pipe shape.

In the meantime, when the inner space of the first shape has the half-pipe shape, the preset location may be a location in a form of two straight lines along a bottom surface in the inner space.

In this case, the conductive material forming unit may form the electrode to be exposed between the first shape and the second shape.

In the meantime, when the inner space of the first shape has the polygonal shape, the preset location may be a corner of a polygon.

In the meantime, the controller may determine an injection amount of the conductive liquid based on a length of the electrode formed in the inner space.

In the meantime, the non-conductive material forming unit and the conductive material forming unit may use one 3D printing technique of fused deposition modeling (FDM), stereolithography (SLA), digital light processing (DLP), selective laser sintering (SLS), and selective laser melting (SLM).

It is to be understood that the foregoing summarized features are exemplary aspects of the following detailed description of the present disclosure without limiting the scope of the present disclosure.

According to the present disclosure, it is possible to minimize manufacturing costs for sensors such as tilt and motion sensors, etc.

Also, according to the present disclosure, it is possible to manufacture a sensor of high reliability compared to conventional sensors since a PCB pattern and additional logic are unnecessary.

Also, according to the present disclosure, it is possible to easily and quickly manufacture a sensor having a desired external shape, a material, a size, etc. according to user needs by using 3D printing

Also, according to the present disclosure, it is possible to manufacture a material property change-resistant sensor by forming an electrode with a conductive material other than a metal electrode.

Effects that may be obtained from the present disclosure will not be limited to only the above described effects. In addition, other effects which are not described herein will become apparent to those skilled in the art from the following description.

### BRIEF DESCRIPTION OF THE DRAWINGS

The above and other objects, features and other advantages of the present disclosure will be more clearly understood from the following detailed description when taken in conjunction with the accompanying drawings, in which:

FIG. 1 is a flowchart illustrating a manufacturing method of tilt and motion sensors by using 3D printing according to an embodiment of the present disclosure;

FIG. 2 is a view illustrating a manufacturing method of tilt and motion sensors by using 3D printing according to an embodiment of the present disclosure;

FIG. 3 is a view illustrating an inner space in a half-pipe shape according to an embodiment of the present disclosure;

FIG. 4 is a view illustrating a sensor having an inner space in a half-pipe shape according to an embodiment of the present disclosure;

FIG. 5 is a view illustrating a sensor having an inner space in a cubic shape according to an embodiment of the present disclosure;

FIG. 6 is a view illustrating tilt and motion detection of a sensor having an inner space in half-pipe and cubic shapes according to an embodiment of the present disclosure; and

FIG. 7 is a block diagram illustrating a configuration of a 3D printer according to an embodiment of the present disclosure.

### DETAILED DESCRIPTION OF THE INVENTION

Hereinbelow, exemplary embodiments of the present disclosure will be described in detail with reference to the accompanying drawings such that the disclosure can be easily embodied by one of ordinary skill in the art to which this disclosure belongs. However, it should be understood that the embodiments may be changed to a variety of embodiments and are not limited to the embodiments described hereinbelow.

When it is determined that the detailed description of the known art related to the present disclosure might obscure the gist of the present disclosure, the detailed description thereof will be omitted. Also, portions that are not related to the present disclosure are omitted in the drawings, and like reference numerals designate like elements throughout the specification.

In the present disclosure, it should be understood that when an element is referred to as being “coupled”, “combined”, or “connected” to another element, it can be directly coupled to the other element or intervening elements may be present therebetween. Also, it should be further understood that an element “comprises”, “includes”, or “has” another element, unless there is another opposite description thereto, an element does not exclude another element but may further include the other element.

In the present disclosure, the terms “first”, “second”, etc. may be used herein to distinguish one element from another element. Unless specifically stated otherwise, the terms “first”, “second”, etc. do not denote an order or importance. Accordingly, a first element of an embodiment could be termed a second element of another embodiment without departing from the scope of the present disclosure. Similarly, a second element of an embodiment could also be termed a first element of another embodiment.

In the present disclosure, components that are distinguished from each other to clearly describe each feature do not necessarily denote that the components are separated. That is, a plurality of components may be integrated into one hardware or software unit, or one component may be distributed into a plurality of hardware or software units. Accordingly, even if not mentioned, the integrated or distributed embodiments are included in the scope of the present disclosure.

In the present disclosure, components described in various embodiments do not denote essential components, and some of the components may be optional. Accordingly, an embodiment that includes a subset of components described in another embodiment is included in the scope of the present disclosure. Also, an embodiment that includes the components described in the various embodiments and additional other components is included in the scope of the present disclosure.

Hereinafter, exemplary embodiment of the present disclosure will be described with reference to the accompanying drawings.

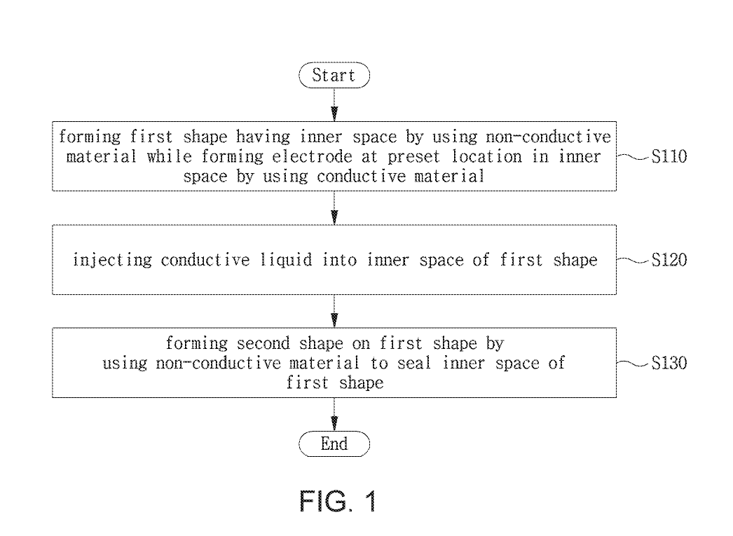

FIG. 1 is a flowchart illustrating a manufacturing method of tilt and motion sensors by using 3D printing according to an embodiment of the present disclosure.

Referring to FIG. 1, tilt and motion sensors may be manufactured by performing steps S110 to S130 in order.

At step S110, a first shape having an inner space is formed by using a non-conductive material while an electrode is formed at a preset location in the inner space by using a conductive material. Alternatively, forming of the first shape and forming of the electrode may be performed in order.

Here, as the non-conductive material, plastic filaments, synthetic resin filaments, curing resin, pottery powder, resin, etc. may be selectively applied according to 3D printing technique. The conductive material may be a plastic material having conductive components such as carbon fiber filaments.

Also, at step S110, the non-conductive material and/or the conductive material may be cured so as to form the first shape and the electrode.

In the meantime, the inner space of the first shape may have one of a polygonal shape and a half-pipe shape.

In the meantime, the preset location at a surface in the inner space may differ based on the shape of the inner space. Specifically, when the inner space has a half-pipe shape, a location in a form of two straight lines along a bottom surface of a half-pipe may be set as the preset location. Also, when the inner space has a polygonal shape, a corner of the polygon may be set as the preset location.

At step S120, conductive liquid may be injected into the inner space of the first shape. Here, the injected amount of the conductive liquid may be controlled based on a length of the electrode formed in the inner space of the first shape. According to an embodiment, the conductive liquid may be injected to submerge the length or height of the electrode in a range of 30% to 70%. When the length or height of the electrode is submerged, for example, when the entire electrode is submerged, tilt and motion information cannot be detected. Also, when the injected amount of the conductive liquid is large, sensitivity of the sensor may be reduced. When the injected amount of the conductive liquid is small, sensitivity of the sensor may be increased.

At step S130, a second shape may be formed on the first shape by using the non-conductive material to seal the inner space of the first shape.

In the meantime, when the inner space has a half-pipe shape at step S110, the electrode may be formed on a portion of a top surface of the first shape beyond the preset location of the inner space of the first shape at step S110 to be exposed between the first shape and the second shape. Change in resistance component caused by being in contact with the conductive liquid and electrodes may be measured through the exposed electrode.

In the meantime, the forming at steps S110 and S130 may be performed by using at least one 3D printing technique of fused deposition modeling (FDM), stereolithography (SLA), digital light processing (DLP), selective laser sintering (SLS), and selective laser melting (SLM).

As described above, tilt and motion sensors may be manufactured by performing steps S110 to S130 in order.

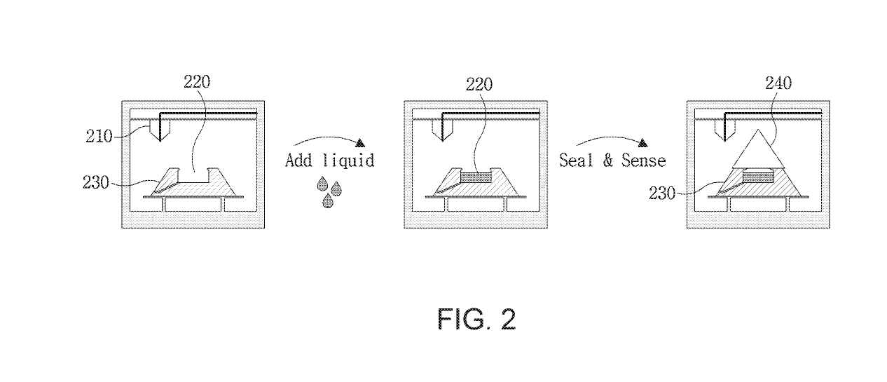

Hereinafter, a manufacturing method of tilt and motion sensors will be described with reference to FIG. 2. In FIG. 2, it is assumed that sensors are manufactured by using FDM 3D printing technique according to the embodiment of the present disclosure.

A first shape 230 having an inner space 220 is formed by discharging a non-conductive material through a discharge head 210 of a 3D printer according to an embodiment of the present disclosure. Simultaneously or sequentially, the discharge head 210 of the 3D printer discharges a conductive material to the inner space 220 of the first shape to form an electrode. Here, although the discharge head 210 is shown as one head, several discharge heads such as a conductive material head and a non-conductive material head may be provided.

Also, the 3D printer injects conductive liquid into the inner space 220 of the first shape 230.

When injection of the conductive liquid into the inner space 220 of the first shape is completed, the 3D printer may discharge the non-conductive material on the first shape 230 to form a second shape 240 so as to seal the inner space 220 of the first shape.

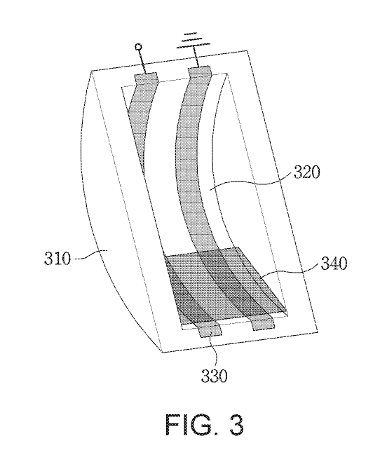

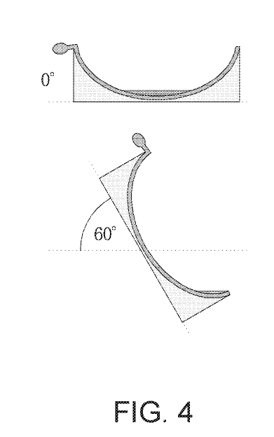

FIGS. 3 and 4 are views illustrating a sensor having an inner space in a half-pipe shape according to an embodiment of the present disclosure.

Referring to FIG. 3, an inner space 320 of a first shape 310 formed by a 3D printer may be formed in a half-pipe shape.

An electrode 330 may be formed as two straight lines 330 along a half-pipe bottom surface in an inner space 320 in a half-pipe shape.

A sensor having an inner space in a half-pipe shape as shown in FIG. 3, may detect a tilt by using the electrode in a half-pipe shape and conductive liquid. Specifically, conductive liquid 340 shorts two electrodes 330 and the length of the electrodes are determined based on the tilt of the sensor. When the length of the electrode is long, a resistance component is increased. Conversely, when the length of the electrode is short, the resistance component is reduced. By using this principle, the tilt of the sensor may be measured based on resistance values of the electrodes formed of a conductive material in a half-pipe shape.

Referring to FIG. 4, the length of the electrode when the sensor maintains a horizontal state (0°) is different from that of when the sensor is tilted at 60 degree angles. In these conditions, resistance component is measured to calculate the tilt.

In the meantime, in a case of a sensor having an inner space in a half-pipe shape as shown in FIGS. 3 and 4, only two electric wires to be connected with two electrodes are required and thus, a cost-effective tilt sensor may be manufactured.

Also, electric wiring is simple and thus, sensor reliability may be increased.

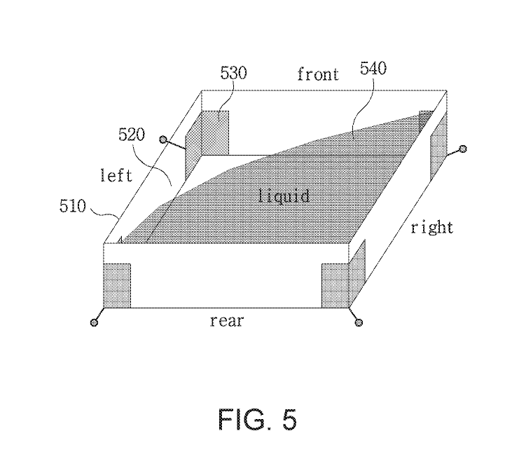

FIG. 5 is a view illustrating a sensor having an inner space in a cubic shape according to an embodiment of the present disclosure.

Referring to FIG. 5, an inner space 520 of a first shape 510 formed by a 3D printer may be formed in a cubic shape.

An electrode 530 may be formed at a corner of the inner space 520 in a cubic shape.

A sensor having an inner space in a cubic shape as shown in FIG. 5 may detect tilt and motion by using an electrode 530 formed at a corner, and conductive liquid 540. Specifically, each electrode is used to measure up, down, left, or right motions of a user, and at least two electrodes inside the sensor may be shorted. When a user moves the sensor up, down, left, or right, the conductive liquid may short the electrode. A user motion may be recognized by identifying the location of the shorted electrode.

Also, the sensor having the inner space as shown in FIG. 5 may detect simple up, down, left, or right motions, as well as motion with direction such as right upward, left upward, etc.

Table 1 below shows the result of detection motions depending on whether or not each electrode of the sensor having the inner space in a cubic shape as shown in FIG. 5 is shorted.

TABLE 1

| Number of shorted | |
|---|---|
| electrode | Motion |
| 4 | Horizontal state (Balance state) |
| 3 | Up, down, left, or right state with |
| | direction (Intermediate State) |
| 2 | Up, down, left, or right state |
| | without direction |
| 0 | Upside down state of a device |
| | (Flipped over state) |

In FIG. 5, it is assumed that the inner space of the first shape is provided in a cubic shape. However, according to an embodiment of the present disclosure, the inner space of the first shape is formed in a polygonal shape, and corners of the polygon are provided with electrodes, whereby a sensor of measuring a user motion can be manufactured.

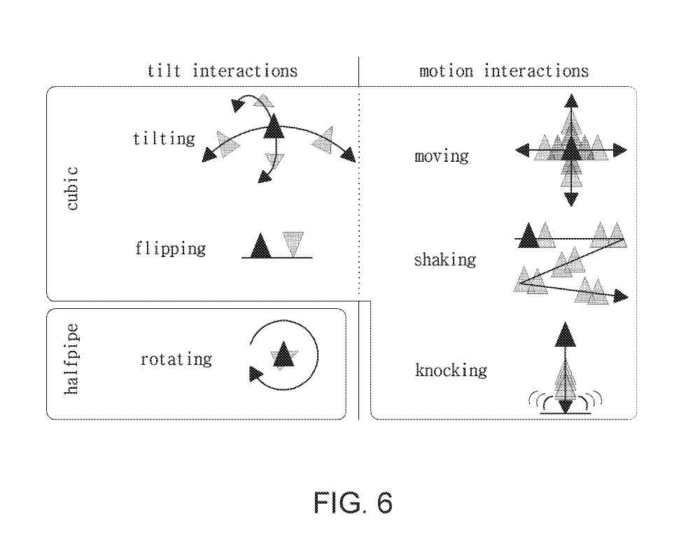

FIG. 6 is a view illustrating tilt and motion detection of a sensor having an inner space in half-pipe and cubic shapes according to an embodiment of the present disclosure.

Referring to FIG. 6, the sensor having the inner space in a half-pipe shape according to the embodiment of the present disclosure may detect tilt and rotation states of the sensor.

In the meantime, the sensor having the inner space in a cubic shape according to the embodiment of the present disclosure may detect simple up, down, left, or right motions, as well as up, down, left, or right motions with direction (tilting) and an upside down state of the sensor (flipping). Also, by combining the detected up, down, left, or right motion information, it is possible to detect various motions such as a motion state in a specific direction (moving), a zigzag or vibration state (shaking), a tap state (knocking), etc.

FIG. 6 shows an example of detecting representative motions (or movements), and various kinds of movements may be detected based on the combination.

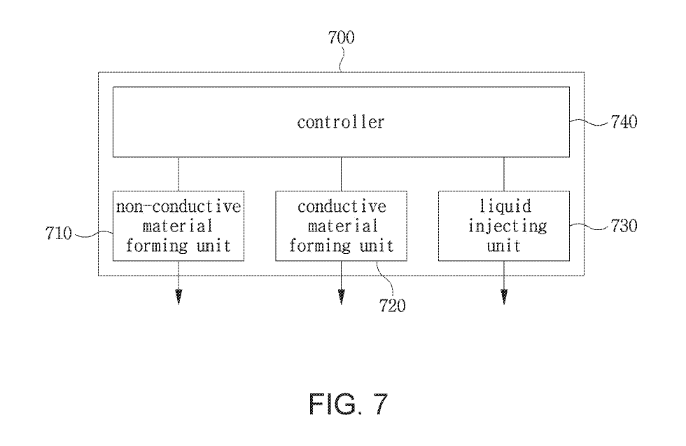

FIG. 7 is a block diagram illustrating configuration of a 3D printer according to an embodiment of the present disclosure.

Referring to FIG. 7, the 3D printer 700 according to the embodiment of the present disclosure may include a non-conductive material forming unit 710, a conductive material forming unit 720, a liquid injecting unit 730, and a controller 740.

The non-conductive material forming unit 710 may form a first shape having an inner space by using a non-conductive material. Here, the inner space of the first shape may have one of a polygonal shape and a half-pipe shape.

In the meantime, the non-conductive material forming unit 710 may form a second shape on the first shape by using the non-conductive material so as to seal the inner space of the first shape.

The conductive material forming unit 720 may form an electrode at a preset location in the inner space by using a conductive material. Specifically, when the inner space of the first shape has a half-pipe shape, the electrode may be formed at a location in a form of two straight lines along the bottom surface of the half pipe. In contrast, when the inner space of the first shape has a polygonal shape, the electrode may be formed at a corner of the polygon.

In the meantime, when the inner space of the first shape has a half-pipe shape, the conductive material forming unit 720 may form the electrode to be exposed between the first shape and the second shape.

Also, the non-conductive material forming unit 710 and the conductive material forming unit 720 may be respectively composed of material storage units storing the non-conductive material and conductive material, heads discharging materials, and curing units curing the discharged materials.

The liquid injecting unit 730 may inject the conductive liquid into the inner space of the first shape.

The controller 740 controls operation of each component of the 3D printer. Specifically, the controller 740 may control each component of the 3D printer according to a 3D model that is input by a user, and may manufacture an object.

The controller 740 may control the non-conductive material forming unit 710 and the conductive material forming unit 720 to form the first shape and the electrode according to the input 3D model. When form of the first shape and the electrode is completed, the controller 740 may control conductive liquid to be injected. Also, the controller 740 may control the non-conductive material forming unit 710 to form the second shape on the first shape.

Also, the controller 740 may determine an injection amount of the conductive liquid based on the length of the electrode formed in the inner space. Specifically, the controller 740 may determine the injection amount of the conductive liquid to submerge the length or height of the electrode in a range of 30% to 70%, in the conductive liquid. When excessively submerged, for example, when the entire electrode is submerged, tilt and motion information cannot be detected. Also, when the injected amount of the conductive liquid is large, sensitivity of the sensor may be reduced. When the injected amount of the conductive liquid is small, sensitivity of the sensor may be increased.

The manufacturing method of a sensor by using 3D printing, and 3D printer therefor have been described with reference to FIGS. 1 to 7.

According to the embodiment of the present disclosure, the manufacturing method of a sensor can minimize manufacturing costs for tilt and motion sensors.

Also, it is possible to manufacture a sensor of high reliability compared to conventional sensors since a PCB pattern and additional logic are unnecessary.

Also, by using 3D printing, it is possible to easily and quickly manufacture a sensor having a desired external shape, a material, a size, etc. according to user needs.

Also, it is possible to manufacture a rust-resistant sensor by forming an electrode with a conductive material other than a metal electrode.

In the meantime, according to an aspect of the present disclosure, software or a computer-readable medium having executable instructions may be provided to perform the manufacturing method of a sensor by using 3D printing. The executable instructions may include: an instruction for forming the first shape having the inner space by using the non-conductive material; an instruction for forming the electrode at a preset location of the inner space by using the conductive material; an instruction for injecting the conductive liquid into the inner space; and an instruction for forming the second shape on the first shape by using the non-conductive material to seal the inner space of the first shape, wherein the instructions are simultaneously or sequentially performed.

Although exemplary methods of the present disclosure are represented as a series of operations for clarity of description, the order of the steps is not limited thereto. When necessary, the illustrated steps may be performed simultaneously or in a different order. To implement the method according to the present disclosure, other steps may be included in addition to the example steps, or some steps may be excluded and the remaining steps may be included, or some steps may be excluded and additional other steps may be included.

The various embodiments of the present disclosure are not all possible combinations but for explaining representative aspects of the present disclosure. The above-described various embodiments of the present disclosure may be independently applied or two or more embodiments thereof may be applied.

Also, various embodiments of the present disclosure may be implemented by hardware, firmware, software, combinations thereof, etc. With hardware implementation, an embodiment may be implemented by one or more application specific integrated circuits (ASICs), digital signal processors (DSPs), digital signal processing devices (DSPDs), programmable logic devices (PLDs), field programmable gate arrays (FPGAs), general processors, controllers, micro-controllers, microprocessors, etc.

The scope of the present disclosure includes software or machine-executable commands (for example, operating system, application, firmware, program, etc.) that enable operation of methods according to various embodiments to be executed on devices or computers, and includes a non-transitory computer-readable medium that may store the software or commands, etc. and may be executed on devices or computers.

What is claimed is:

1. A manufacturing method of a sensor by using 3D printing, the manufacturing method comprising:
forming a first shape having an inner space by using a non-conductive material, and forming an electrode at a preset location in the inner space by using a conductive material;
injecting conductive liquid into the inner space; and
forming a second shape on the first shape by using the non-conductive material to seal the inner space of the first shape.

2. The manufacturing method of claim 1, wherein the inner space of the first shape has one of a polygonal shape and a half-pipe shape.

3. The manufacturing method of claim 2, wherein when the inner space of the first shape has the half-pipe shape, the preset location is a location in a form of two straight lines along a bottom surface in the inner space.

4. The manufacturing method of claim 3, wherein the electrode is formed to be exposed between the first shape and the second shape.

5. The manufacturing method of claim 2, wherein when the inner space of the first shape has the polygonal shape, the preset location is a corner of a polygon.

6. The manufacturing method of claim 1, wherein the injecting of the conductive liquid into the inner space is controlled based on a length of the electrode formed in the inner space.

7. The manufacturing method of claim 1, wherein the forming is performed by using one 3D printing technique of fused deposition modeling (FDM), stereolithography (SLA), digital light processing (DLP), selective laser sintering (SLS), and selective laser melting (SLM).

8. A 3D printer for manufacturing a sensor, the 3D printer comprising:
a non-conductive material forming unit forming a first shape having an inner space by using a non-conductive material;
a conductive material forming unit forming an electrode at a preset location in the inner space by using a conductive material;
a liquid injecting unit injecting conductive liquid into the inner space of the first shape; and
a controller controlling the non-conductive material forming unit to form a second shape on the first shape by using the non-conductive material so as to seal the inner space of the first shape.

9. The 3D printer of claim 8, wherein the inner space of the first shape has one of a polygonal shape and a half-pipe shape.

10. The 3D printer of claim 9, wherein when the inner space of the first shape has the half-pipe shape, the preset location is a location in a form of two straight lines along a bottom surface in the inner space.

11. The 3D printer of claim 10, wherein the conductive material forming unit forms the electrode to be exposed between the first shape and the second shape.

12. The 3D printer of claim 9, wherein when the inner space of the first shape has the polygonal shape, the preset location is a corner of a polygon.

13. The 3D printer of claim 8, wherein the controller determines an injection amount of the conductive liquid based on a length of the electrode formed in the inner space.

14. The 3D printer of claim 8, wherein the non-conductive material forming unit and the conductive material forming unit perform the forming by using one 3D printing technique of fused deposition modeling (FDM), stereolithography (SLA), digital light processing (DLP), selective laser sintering (SLS), and selective laser melting (SLM).
